(19) United States
(12) Patent Application Publication
(10) Pub. No.: US 2004/0125903 A1
(43) Pub. Date: Jul. 1, 2004

(54) Digital phase detection with jitter filter

(76) Inventor: Mel Bazes, Haifa (IL)

Correspondence Address: BLAKELY, SOKOLOFF, TAYLOR & ZAFMAN LLP, Seventh Floor, 12400 Wilshire Boulevard, Los Angeles, CA, 90025-1026, US

(21) Appl. No.: 10/335,012

(22) Filed: Dec. 31, 2002

(51) Int. Cl. H03D 3/24

(52) U.S. Cl. 375/375

(57) ABSTRACT

A digital phase detector and jitter filter. For one aspect, a digital phase detector receives first and second input signals and provides at least one of a digital LEAD and LAG output signal. Multiple inputs of a digital filter are collectively coupled to receive the digital output signal from the digital phase detector. The digital filter provides a multi-bit digital phase error output signal to indicate a phase error between the first and second signals. Phase-lock is indicated when the phase error output signal indicates a value substantially in the center of the range of possible integer combinations that may be provided by the multi-bit output signal.

An embodiment of the present invention relates to the field of integrated circuits and, more particularly, to phase detection and jitter filtering.

### BACKGROUND

Phase-locking is used in applications such as clock and data recovery (CDR), where clock transitions are embedded in a signal. CDR may be used in a variety of applications such as recovering clock and data information from phase-encoded serial data associated with input/output buses, networks and optical networks, for example, where it is advantageous to provide for high-speed communications with fewer signals. Other benefits of a signaling approach relying on CDR may include, improved noise immunity, better reliability and lower power consumption as compared to similar approaches that do not use CDR.

For any signaling approach, including one in which CDR is used, it is important to ensure that errors are not introduced in receiving and/or interpreting the signals.

### BRIEF DESCRIPTION OF THE DRAWINGS

The present invention is illustrated by way of example and not limitation in the figures of the accompanying drawings in which like references indicate similar elements, and in which:

FIG. 1 is a timing diagram showing waveforms that may be associated with an example clock and data recovery implementation.

FIG. 2 is a timing diagram showing waveforms illustrating an example of phase-locking in the presence of jitter.

FIG. 3 is a high-level schematic diagram of a prior analog phase detector and jitter filter.

FIG. 4 is a high-level block diagram of a digital phase detector and jitter filter according to one embodiment.

FIG. 5 is a block diagram of a digital low-pass filter of one embodiment.

FIG. 6 is a high-level block diagram of a portion of an exemplary clock and data recovery circuit in which the digital phase detector and jitter filter of FIG. 4 may be used.

FIG. 7 is a block diagram of an exemplary system of one embodiment in which the exemplary clock and data recovery circuit of FIG. 6 and/or the digital phase detector and jitter filter of FIG. 4 may be advantageously used.

FIG. 8 is a flow diagram of a method of one embodiment for digital phase detection and jitter filtering.

### DETAILED DESCRIPTION

A method and apparatus for digital phase detection and jitter filtering are described. In the following description, particular types of applications, system configuration, bus protocols and circuits are described for purposes of illustration. It will be appreciated, however, that other embodiments are applicable to other types of applications, system configurations, bus protocols and/or circuits.

For one embodiment, a digital phase detector includes first and second inputs to receive first and second signals and has an output to provide one of a LEAD and a LAG signal. A digital filter has at least a first data input coupled to the output of the digital phase detector and an output to provide a digital phase error signal to indicate a phase error between the first and second signals.

For some embodiments, the digital filter has N data inputs, all of which are coupled to receive the output signal from the digital phase detector, such that all inputs have the same value. Further, the digital filter has N data output signal lines. The digital filter indicates that phase lock of the first and second signals has been achieved when the output value indicated by the multi-bit output signal of the digital filter is substantially in the middle of the range of integer combinations that may be represented by the output signal.

Details of these and other embodiments are provided in the description that follows.

As described above, clock and data recovery (CDR) may be used for a variety of different applications. Where CDR is used, it is generally important to ensure, to the extent possible, that clock and data signals are reliably communicated and received. For CDR, because a clock signal is recovered from a received data signal, jitter associated with the data signal may be particularly problematic and, unless filtered out, may introduce phase error in the recovered clock signal. Phase error in the recovered clock signal increases the likelihood of errors in the recovered data.

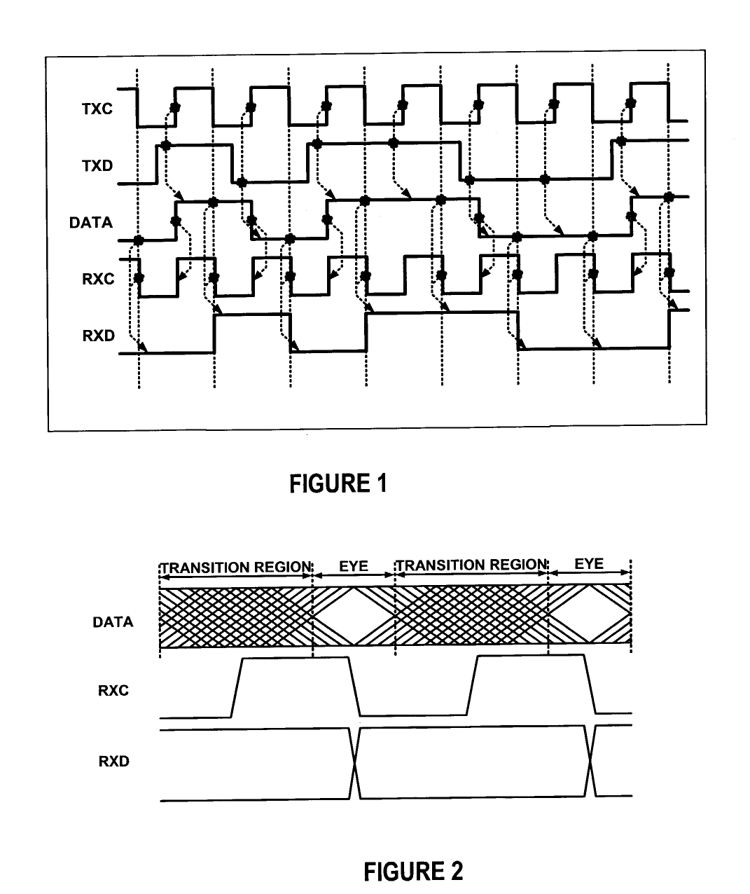

For example, FIG. 1 illustrates, in simplified form, basic waveforms that may be used in clock and data recovery (CDR). For the waveforms in FIG. 1, a simple non-return-to-zero (NRZ) encoding scheme, for example, is represented. It will be appreciated, however, that the invention described below may be applied to other types of encoding schemes, such as phase-encoding schemes in which the encoded data must be sampled at relatively precise points with respect to embedded transitions, such as Manchester encoding or Miller encoding.

In FIG. 1, TXC represents a reference clock signal associated with a transmitting device and TXD indicates the data to be transmitted. For this example, a rising edge of TXC causes the signal TXD to be sampled in order to generate a signal DATA to be transmitted.

In this simple example, the transitions of the DATA signal comprise the embedded clock information. At a receiving device, a clock and data recovery circuit may extract or recover the embedded clock signal by locking onto clock transitions in the DATA signal and generating a recovered clock signal RXC with a specific delay (i.e., phase) with respect to the transitions in the DATA signal. Ideally, the sampling edge of the recovered clock signal RXC, is located exactly in the midpoint of the DATA signal transitions.

RXC is then used to sample the DATA signal to produce an extracted or recovered data signal RXD, which replicates (in a shifted form), the original data signal TXD. It will be noted that, for purposes of simplicity, the phase difference between the version of the DATA signal that is transmitted and the version of the DATA signal that is received is not shown in FIG. 1. It will be appreciated, however, that a substantial phase difference may exist between the transmitted and received versions of the DATA signal. This phase difference, in general, does not affect CDR.

In typical clock and data recovery implementations, the received DATA signal may include a substantial amount of phase noise, also referred to as jitter. Unless this jitter is filtered out as described above, phase error may be introduced into the recovered clock signal RXC. Phase error in the RXC signal can introduce errors into the recovered data signal RXD.

FIG. 2 is a timing diagram illustrating an exemplary received signal DATA corrupted by jitter as it may be observed, for example, on a laboratory oscilloscope. Instead of seeing clean, sharp transitions of the DATA signal, there is actually a blur created by the jitter of the received DATA signal. To properly recover a signal from the DATA signal corrupted by jitter, a clock and data recovery circuit must be capable of identifying the center of this blur and phase-locking the rising edge of the RXC signal to that position. If the clock and data recovery circuit fails to phase-lock RXC to the proper point, then the falling edge of RXC, which causes the DATA signal to be sampled in the relatively narrow “eye” region outside of the jitter-corrupted transition region, may cause the DATA signal to be sampled incorrectly, such that errors are created in the RXD signal.

The location of a transition in a particular clock period has two components: a DC component and an AC component. The DC component constitutes the location of the transition in the absence of jitter, while the AC component constitutes the error in the observed transition location created by the jitter. In a conventional CDR implementation, to find the phase of a clock signal with respect to the transition region of the DATA signal, the transition region of the DATA signal is sampled continuously by a phase detector, and then the AC component of the signal is filtered out using a low-pass filter. After filtering, the residual DC component provides an estimate of the transition location in the transition region.

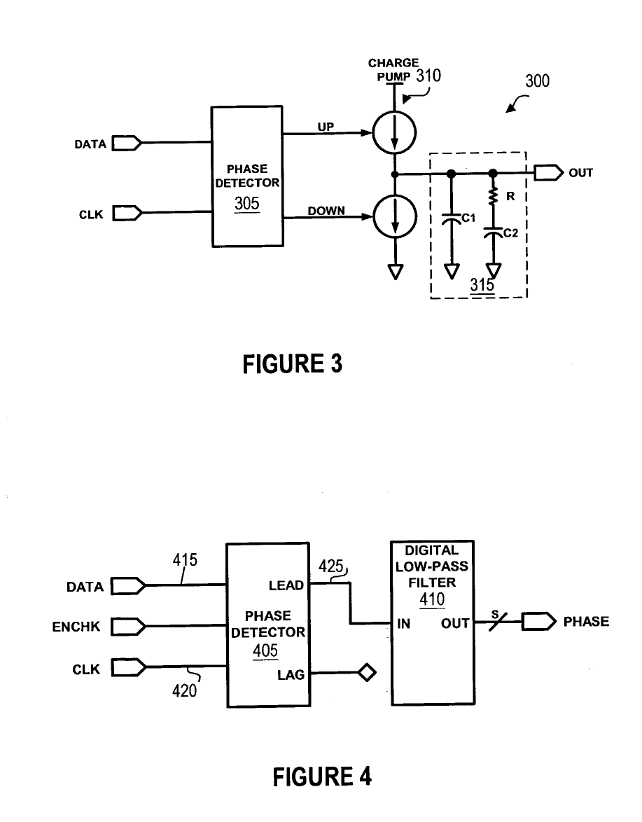

Prior approaches to phase-locking primarily rely on analog techniques for phase-locking and jitter filtering. FIG. 3 illustrates a relatively common analog technique that uses a phase detector 305 combined with a charge pump 310 and a filter 315. For the approach shown in FIG. 3, depending on the phase relationship between input DATA and CLK signals, the phase detector 305 controls the charge pump 310 to send either short positive (UP) or short negative (DOWN) current pulses to charge the output node OUT up or down. The current pulses are integrated by a capacitor C1 in order to convert them into voltage steps. An optional filter 315 that may include, for example, a resistor R and a capacitor C2, slows down the response of the circuit 300 to maintain closed-loop stability of a system in which the circuit 300 is implemented.

When phase-lock is attained, the number of UP pulses equals the number of DOWN pulses, assuming the pulses are identical in terms of the amount of charge they transfer. At that point, the output voltage of the phase-detector 305 plus filter 315 is substantially steady except for a small ripple caused by the successive UP and DOWN pulses.

While the approach shown in FIG. 3 provides for phase-locking, there are some drawbacks. First, the circuit 300 includes analog elements and, thus, is relatively sensitive to variations in supply voltage, temperature and processing parameters. Second, the output of the circuit 300 is a voltage that, as mentioned, is dependent on supply voltage, temperature and processing parameters and, therefore, is not easily translatable into phase information. Further, it is difficult to precisely set the bandwidth of the circuit 300 due to its analog nature.

FIG. 4 is a high-level block diagram of a digital phase-detector 405 and digital jitter filter 410 of one embodiment that may be advantageously used to perform phase-locking in, for example, clock and data recovery applications. It will be appreciated that the digital phase detector and jitter filter of various embodiments may alternatively be used for other types of applications. The digital phase detector 405 may be implemented using any one of a wide variety of existing phase detectors that provide at least one of a LEAD or LAG output signal.

An example of a phase detector that may be used for one embodiment to provide the phase detector 405 is described in U.S. Pat. No. 5,744,983 entitled, “Phase Detector with Edge-Sensitive Enable and Disable,” Issued Apr. 28, 1998 to Mel Bazes, the inventor of the present invention, and assigned to the assignee of the present invention. It will be appreciated that other types of digital phase detectors that provide at least one of a LEAD or LAG output signal may instead be used for various embodiments.

For the embodiment shown in FIG. 4, the phase detector 405 includes a data input 415 to receive a data signal, a clock (CLK) input 420 to receive a clock signal and an enable check input to receive an enable check (ENCHK) signal that determines when the phase difference between the data and clock signals is checked. The phase detector 405 further includes a LEAD output 425 to provide a LEAD signal that transitions between a logic high value (1) and a logic low value (0) depending on whether the phase of the signal at the data input 415 leads or lags the phase of the CLK signal at the input 420.

For the embodiment shown in FIG. 4, inputs of the digital filter 410 are coupled to the LEAD output of the phase detector 405 as described in more detail below. It will be appreciated that, for other embodiments, a LAG output of the phase detector may be used instead where the signal on the LAG output transitions in a similar (but opposite) manner in response to the relative phases of two input signals.

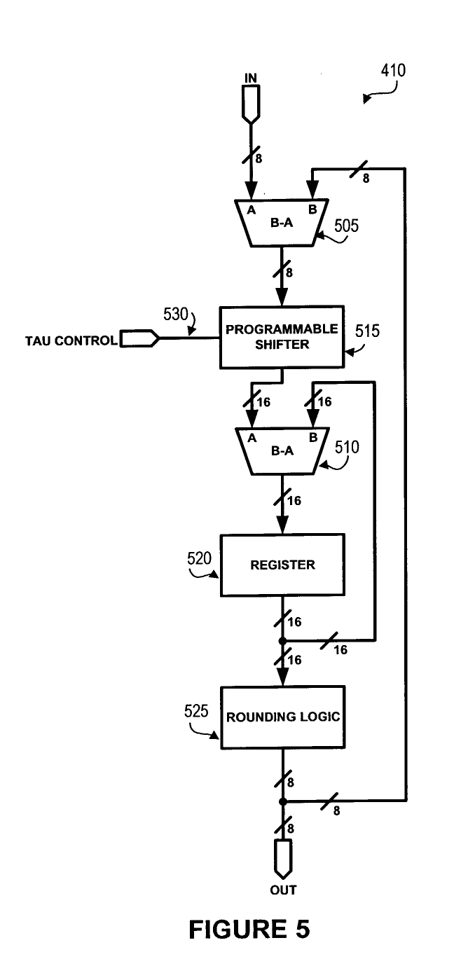

The digital low-pass jitter filter 410 of one embodiment is shown in further detail in FIG. 5. The digital low-pass filter 410 includes subtractors 505 and 510, a programmable shifter 515, a register 520, and rounding logic 525. The operation of each of these elements is described in more detail below. While a simple one-pole, low-pass filter is shown in FIG. 5, for other embodiments, a different type of digital filter, including, for example, a filter with several poles, may be used. The particular type of digital filter selected to be used may be dependent upon a variety of factors such as, for example, available bandwidth and desired level of jitter removal.

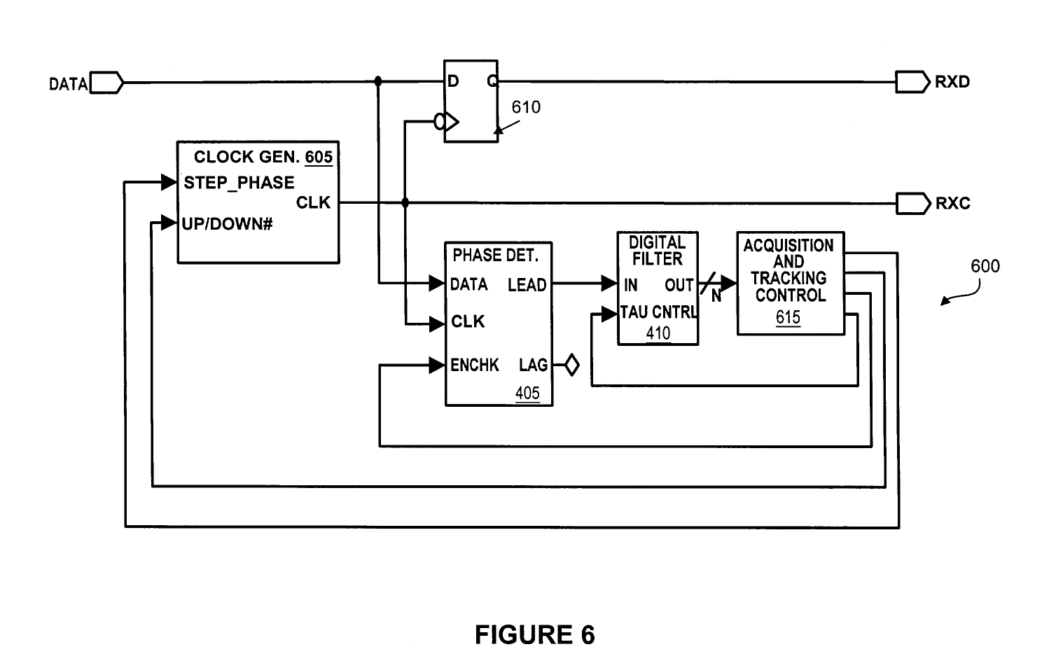

FIG. 6 is a high-level block diagram of a portion 600 of an exemplary clock and data recovery circuit in which the digital phase detector 405 and digital jitter filter 410 may be used. As shown in FIG. 6, in addition to the digital phase detector 405 and jitter filter 410, the circuit 600 includes a clock generator 605 to synthesize the recovered clock signal (RXC). The clock generator 605 has an output coupled to provide the RXC signal to an input of the phase detector 405. The clock and data recovery circuit 600 also includes a flip-flop 610 that is clocked by the recovered clock signal RXC to provide the recovered data signal RXD at an output, and an acquisition and tracking control circuit 615 that is coupled to receive the output of the digital jitter filter 410. The acquisition and tracking control circuit 615 has outputs that are coupled to control the clock generator 605, phase detector 405 and digital jitter filter 410 as described in more detail below.

Referring to FIGS. 4, 5, and 6, in operation, the phase detector 405 receives the encoded data signal DATA at the data input 415, and the recovered clock signal RXC at the CLK input 420. RXC is provided with an initially undefined phase relationship with respect to the incoming data signal DATA. At the start of reception, an acquisition procedure takes place during which the phase of RXC is varied until it is correctly located with respect to the incoming data signal DATA and lock is achieved. Depending on whether the recovered clock signal RXC leads or lags transitions of the DATA signal, the signal at the LEAD output is either a 1 or a 0.

The digital low-pass jitter filter 410 samples the LEAD output 425 of the phase-detector 405 every clock cycle of a reference clock signal.

The reference clock signal having a clock period T_{P} is provided to each of the clocked elements of the clock and data recovery circuit 600, including, for example, the clock generator 605, the digital jitter filter 410, and the acquisition and tracking control circuit 615, to synchronize various circuits in the clock and data recovery circuit 600. The physical connections that provide the reference clock signal to each of the clocked circuits are not shown in the figures to avoid unnecessarily obscuring the invention.

Conventionally, a digital filter has N inputs and N outputs, where N is the width of the binary integer representation of the data processed by the filter. Thus, a digital filter can have any of 2^{N} inputs and provide any of 2^{N} outputs. For the circuit of FIG. 4, however, the digital low-pass filter 410 only receives one of two input values: either a logical 0 or logical 1 from a single wire output of the phase detector 405.

For one embodiment, all of the multiple inputs of the digital filter 410 are effectively shorted together such that, in response to receiving the sampled LEAD output signal, the input value to the digital filter 410 is converted into binary integers. For example, where N=8, the filter 410 converts the input into either “11111111” (the maximum possible input value) or “00000000” (the minimum possible input value) depending on whether the input is a “1” or a “0”, respectively. It will be appreciated that N may be a different value for other embodiments.

The operation of the digital low-pass filter 410 takes advantage of the fact that, when the recovered clock (RXC in the example above) is centered in the transition region of the DATA signal, approximately 50% of the transitions of the DATA signal will lead the clock signal transition and 50% will lag. So, if phase-lock has been attained, the filter 410 output will be in the center of the range of the 2^{N} integer combinations that may be indicated by the output signal.

Because the range of values for binary integers is even, two values may be assigned to indicate phase-lock. For the example in which N=8, “01111111” (=127d) and “10000000” (=128d) may be assigned as the values indicating phase-lock. Where the output of the digital filter 410 is different from either of these two values, the phase of the recovered clock signal RXC is corrected in the direction that will bring the filter 410 output towards one of these values.

More particularly, once the sampled signal has been converted into an N-bit integer (where N=8 in the embodiment shown in FIG. 4), the subtractor 505 subtracts the N-bit integer data input from an output of the digital filter 410 to generate an error value that is provided to the programmable shifter 515. The digital jitter filter 410 has a variable time constant controlled by a control signal TAU_CONTROL, also referred to herein as a time constant control signal, that is provided by the acquisition and tracking control circuit as described in more detail below. The shifter 515 shifts the error value according to the TAU_CONTROL signal, which controls and varies the shift amount of the error value in order to generate an attenuated error.

At the start of reception of a new data packet, the shift amount provided by the shifter 515 is varied in order to quickly lock onto the frequency of transitions in the input signal. The attenuated error is then applied to the subtractor 510, which subtracts the attenuated error from the unrounded output of the filter 410 to generate an updated filter output. The updated filter output is stored in the register 520, which may, for example, be a D-type register. The updated filter output is provided by the register 520 to rounding logic 525 to generate an output OUT of the filter 410.

With continuing reference to FIG. 5, in equation form, the inputs to the subtractor 505 are IN(n) and OUT(n), where n is the particular period of the reference clock signal RCLK. The output of the programmable shifter 515 is, therefore, given by

SHIFTER_OUT(n)=2^{-SA}·[OUT(n)−IN(n)], Equation 1

where SA is the shifter shift amount.

The inputs to the second subtractor 510 are SHIFTER_OUT(n) and OUT(n). Thus, the second subtractor 510 output is given by

$$\begin{matrix}SECOND\_SUBTRACTOR \_OUT ( n ) = OUT ( n ) - SHIFTER\_OUT ( n ) \\ = OUT ( n ) - {2}^{- SA} \cdot [ OUT ( n ) - IN ( n ) ] \\ = ( 1 - {2}^{- SA} ) \cdot OUT ( n ) + {2}^{- SA} \cdot IN ( n ) .\end{matrix} \qquad Equation 2$$

SECOND_SUBTRACTOR_OUT(n) is input to the register 520. The register 520 output is OUT(n) and is just equal to the register 520 input on the previous clock, i.e., on clock n-1. Thus, the filter output OUT(n) is given by

OUT(n)=(1−2^{-SA})·OUT(n−1)+2^{-SA}·IN(n−1). Equation 3

Solving Equation 3 recursively, provides

$$\begin{matrix}OUT ( n ) = ( 1 - {2}^{- SA} ) \cdot OUT ( n - 1 ) + {2}^{- SA} \cdot IN ( n - 1 ) \\ = ( 1 - {2}^{- SA} ) \cdot [ ( 1 - {2}^{- SA} ) \cdot OUT ( n - 2 ) + {2}^{- SA} \cdot IN ( n - 2 ) ] + {2}^{- SA} \cdot IN ( n - 1 ) \\ = {( 1 - {2}^{- SA} )}^{2} \cdot OUT ( n - 2 ) + {2}^{- SA} \cdot [ ( 1 - {2}^{- SA} ) \cdot IN ( n - 2 ) + {2}^{- SA} \cdot IN ( n - 1 ) \\ = {( 1 - {2}^{- SA} )}^{3} \cdot OUT ( n - 3 ) + {2}^{- SA} \cdot [ {( 1 - {2}^{- SA} )}^{2} \cdot IN ( n - 3 ) + ( 1 - {2}^{- SA} ) \cdot IN ( n - 2 ) + IN ( n - 1 ) ] \\ ⋮ \\ = {( 1 - {2}^{- SA} )}^{n} \cdot OUT ( 0 ) + {2}^{- SA} \cdot [ {( 1 - {2}^{- SA} )}^{n - 1} \cdot IN ( 0 ) + {( 1 - {2}^{- SA} )}^{n - 2} \cdot IN ( 1 ) + … + \\ ( 1 - {2}^{- SA} ) \cdot IN ( n - 2 ) + IN ( n - 1 ) ] \\ = {( 1 - {2}^{- SA} )}^{n} \cdot OUT ( 0 ) + {2}^{- SA} \cdot {\sum }_{i = 1}^{n} {( 1 - {2}^{- SA} )}^{i - 1} \cdot IN ( n - i ) \\ = {( 1 - {2}^{- SA} )}^{n} \cdot OUT ( 0 ) + \frac{{2}^{- SA}}{1 - {2}^{- SA}} \cdot {\sum }_{i = 1}^{n} {( 1 - {2}^{- SA} )}^{i} \cdot IN ( n - i ) .\end{matrix} \qquad Equation 4$$

From Equation 4, it can be seen that OUT(n) has two basic components: one that depends on OUT(0) and one that depends on IN(n). Since the term (1−2^{-SA})ⁿ approaches 0 asymptotically, the component that depends on OUT(0) is completely negligible in the steady-state. So the only component of interest is the component that depends on IN(n).

The impulse response of the filter, i.e., its response to an input given by IN(0)=1 and IN(i)=0 for i 0 is now calculated. In this calculation, the component that depends on OUT(0) is disregarded since it is completely negligible in the steady-state. Substituting IN(0)=1 into Equation 4 and letting IN(i)=0 for i 0 results in

$$OUT ( n ) = \frac{{2}^{- SA}}{1 - {2}^{- SA}} \cdot {( 1 - {2}^{- SA} )}^{n} . \qquad Equation 5$$

Equation 5 can be rewritten as

OUT(n)=K·e^{-t/τ}, Equation 6

where τ is the filter time constant and K equals 2^{-SA}/(1−2^{--SA}). Noting that the number of elapsed clocks n is given by t/T_{P}, where T_{P} is the clock period, and equating Equation 5 to Equation 6,

e^{-t/τ}=(1−2^{-SA})^{t/T}^{_{P}}. Equation 7

Solving Equation 7 for τ.

$$τ = \frac{1}{2 π \cdot {f}_{P}} = \frac{{T}_{P}}{ln ( 1 - {2}^{- SA} )} , \qquad Equation 8$$

where f_{P} is the filter pole frequency.

Solving Equation 8 for f_{P},

$${f}_{P} = - \frac{ln ( 1 - {2}^{- SA} )}{2 π \cdot {T}_{P}} \qquad Equation 9$$

The TAU_CONTROL signal is used to control the filter bandwidth by varying the filter pole location according to Equation 9. When acquisition starts, SA is forced to be 0, thereby increasing the filter 410 bandwidth to “∞.” As acquisition progresses, the SA value is gradually increased until its maximum value is attained at the end of acquisition, at which time, the bandwidth is its final, minimum value. In this manner, acquisition is facilitated by decreasing the time constant at the start of acquisition, thereby making the clock and data recovery loop react more quickly to phase changes made by the acquisition and tracking control circuit during the acquisition phase. The time constant is then increased to maximum when steady-state is achieved and the circuit is only tracking.

Referring to FIG. 6, the multi-bit output of digital filter 410 is provided to the acquisition and tracking control circuit 615. The acquisition and tracking control circuit 615 determines whether lock has been achieved by determining whether the output value is substantially equal to the middle of the range of possible output values. For one embodiment, this is accomplished by comparing the output of the digital filter 410 to the predetermined value(s) described above that indicate whether lock has been achieved. Based on the result of this comparison, the acquisition and tracking control circuit 615 provides output signals TAU CONTROL as described above, and one or more signals (e.g STEP_PHASE and/or UP/DOWN# signals shown in FIG. 6) to the clock generator 605 to control the phase of the recovered clock signal RXC.

The acquisition and tracking control circuit 615 is a digital control circuit that receives information on the recovered clock (RXC) phase and corrects it with respect to the incoming data in order to sample the incoming data substantially in the center of its eye. The configuration and operation of the acquisition and tracking control circuit 615 for a particular embodiment is dependent upon a variety of factors including the particular encoding scheme used, and phase resolution, for example.

Some encoding schemes, for example, may include an acquisition phase in which the filter time constant (TAU) must initially be shortened as much as possible and then gradually lengthened until steady-state is achieved as described above. Other encoding schemes, however, may not have this requirement if acquisition is a one-time event that occurs only at power-up reset or startup, but not again afterwards.

Regarding phase resolution, if high phase resolution is required, then the acquisition and tracking control circuit 615 is designed to make a large number of small phase corrections in the course of arriving at steady-state. Alternatively, if only low phase resolution is needed, then the acquisition and tracking control circuit 615 may be designed to generate a small number of relatively large phase corrections in the course of arriving at the steady-state.

The clock generator 605 may be implemented using any of a variety of well-known clock generators that may be controlled in the manner described herein to provide a clock signal in a desired frequency range and that provide the desired characteristics such as voltage levels, etc. The STEP_PHASE and UP/DOWN# signals operate in tandem to control the clock generator 605 when making phase corrections to the RXC signal. For one embodiment, when STEP_PHASE is low, no phase correction is made and the UP/DOWN# signal is a “don't care.” When STEP_PHASE is high, a single unit phase correction is made to RXC by the clock generator 605, where the UP/DOWN# signal indicates to the clock generator 605 the direction of the phase correction to be applied to the RXC signal. The term “unit phase correction” refers to the basic phase change that the clock generator 605 is designed to make. Other approaches to controlling generation of a recovered clock signal in response to receiving a digital output signal as described herein are within the scope of various embodiments.

Thus, the embodiments described above provide a fully digital approach to phase-locking that addresses many of the drawbacks of prior analog approaches. In particular, the phase-locking approach described herein is substantially immune to variations in supply voltage, temperature and processing parameters. Further, the digital jitter filter provides the transition phase in digital numerical form that may be more easily processed as compared to analog counterparts.

As described above, the bandwidth of the digital phase detection and jitter filter of various embodiments may be set with high precision such that even slight frequency variations between a transmitter and receiver can be tracked. Additionally, during the acquisition portion of clock and data recovery, the digital phase detection and jitter filter approach of some embodiments facilitates bandwidth variation from an initial high value for rapid homing-in on the center of the transition region, to the final value when acquisition is complete. Such bandwidth variation may be impractical to implement in prior analog approaches.

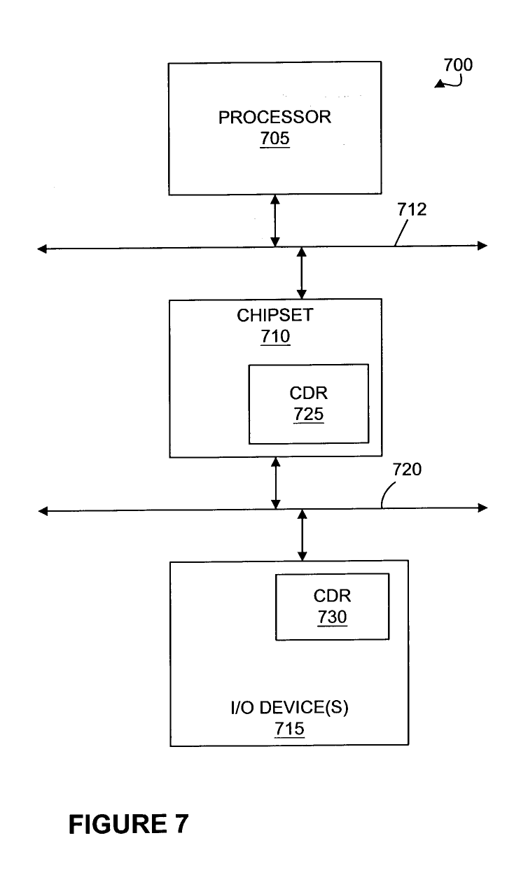

Referring now to FIG. 7, an exemplary system 700 of one embodiment is shown in which the phase-locking approach of various embodiments may be advantageously implemented. The system 700 is a personal computer system. It will be appreciated, however, that for other embodiments, other types of systems, such as workstations, handheld devices, networking systems or devices, etc. may benefit from the phase-locking approach of one or more embodiments.

The system 700 includes a processor 705, a chipset 710, which may include, for example, a memory controller and an I/O controller coupled to the processor 705 over a bus 712, and one or more I/O devices 715, such as a network card, a modem card or other I/O device, coupled to the chipset 710 by an I/O bus 720. For one embodiment, the I/O bus is a peripheral component interconnect (PCI) Express bus in accordance with the PCI Express protocol promulgated by the PCI special interest group (PCI SIG). For other embodiments, a different type of I/O bus may be used.

For the embodiment shown in FIG. 7, each of the chipset 710 and one or more of the I/O device(s) 715 includes a clock and data recovery circuit 725 and 730, respectively, one or more of which may be similar in configuration and operation to the clock and data recovery circuit of FIG. 6 that implements the digital phase-locking approach of various embodiments. In this manner, high-speed I/O communications may be facilitated as described above.

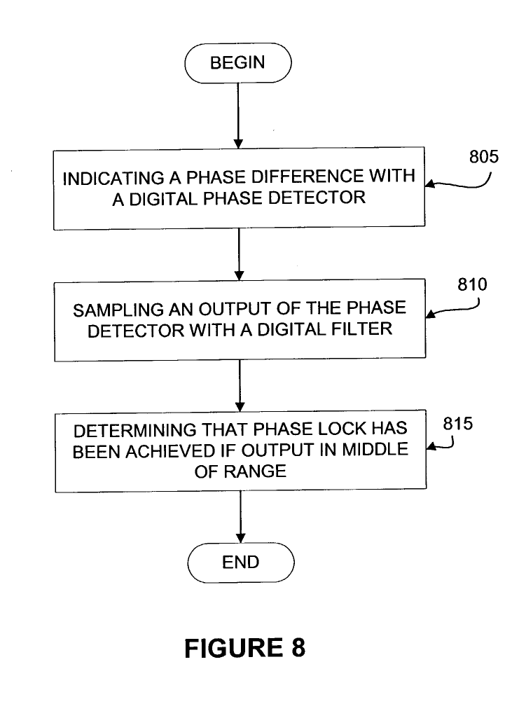

FIG. 8 is a flow diagram showing the phase-locking method of one embodiment. At processing block 805 a phase difference between first and second input signals is indicated using a digital phase detector. At block 810, an output of the phase detector is sampled with a digital filter and an associated digital filter output signal is provided. It is then determined that phase lock has been achieved in response to detecting that the digital filter output signal is substantially in a middle of a range of possible digital filter output signals at block 815.

Thus, a digital phase detector and jitter filter and method for phase-locking are described. In the foregoing specification, the invention has been described with reference to specific exemplary embodiments thereof. It will be appreciated that various modifications and changes may be made thereto without departing from the broader spirit and scope of the invention as set forth in the appended claims. The specification and drawings are, accordingly, to be regarded in an illustrative rather than a restrictive sense.

What is claimed is:

1. An apparatus comprising:
a digital phase detector including first and second inputs to receive first and second signals, the digital phase detector having an output to provide one of a digital LEAD and LAG output signal; and
a digital filter having at least a first data input coupled to the output of the digital phase detector, the digital filter having an output to provide a digital phase error signal to indicate a phase error between the first and second signals.

2. The apparatus of claim 1 wherein
the digital filter includes N data inputs including the first data input, the N data inputs all being coupled to the output of the digital phase detector such that all of the data inputs of the digital filter receive a same logical data value.

3. The apparatus of claim 2 wherein the digital filter is a digital low-pass filter.

4. The apparatus of claim 2 wherein
the digital filter is to indicate that phase lock of the first and second signals has been achieved by outputting a value substantially in a center of a range of 2^{N} possible integer combinations for the digital filter.

5. The apparatus of claim 1 wherein
the first signal is a phase-encoded data signal and the second signal is a clock signal, and wherein the digital phase error signal is to control circuitry to provide a recovered data signal and a recovered clock signal.

6. The apparatus of claim 1 wherein
the digital filter is coupled to receive a time constant control signal, the time constant control signal to cause a time constant of the digital filter to decrease at a start of an acquisition phase and to cause a time constant of the digital filter to increase in response to phase lock of the first and second signals being achieved.

7. A clock and data recovery circuit comprising:
a digital phase detector to receive a first phase-encoded data signal and a first clock signal, an output of the digital phase detector to indicate whether the first phase-encoded data signal leads or lags the first clock signal; and
a digital filter having N inputs coupled to receive a single output signal from the digital phase detector, the digital filter to provide an N-bit output signal, the clock and data recovery circuit to indicate phase-lock in response to the digital filter output signal being substantially in a center of a range of possible values for the output signal.

8. The clock and data recovery circuit of claim 7 wherein the digital filter is a low pass filter.

9. The clock and data recovery circuit of claim 8 wherein the digital low pass filter is a single pole low pass filter.

10. The clock and data recovery circuit of claim 7, wherein the digital filter output signal is to at least partially control a clock generator to provide a recovered clock signal.

11. The clock and data recovery circuit of claim 10, wherein the digital filter is coupled to receive a time constant control signal, the time constant control signal to cause a time constant of the digital filter to decrease at a start of acquisition and to cause a time constant of the digital filter to increase substantially to a maximum time constant for the digital filter in response to phase lock of the first phase-encoded signal and the first clock signal being achieved.

12. A method comprising:
indicating a phase difference between first and second input signals using a digital phase detector;
sampling an output of the phase detector with a digital filter and providing an associated digital filter output signal; and
determining that phase lock has been achieved in response to detecting that the digital filter output signal is substantially in a middle of a range of possible digital filter output signals.

13. The method of claim 12 wherein
indicating the phase difference between first and second signals includes providing one of a lead or lag signal to indicate whether the first input signal leads or lags the second input signal.

14. The method of claim 13 wherein
indicating the phase difference between first and second signals includes indicating a phase difference between a phase-encoded data signal and a clock signal.

15. The method of claim 14 wherein
sampling the output of the phase detector includes effectively coupling all inputs of the digital filter together such that all inputs of the digital filter receive the sampled output signal.

16. The method of claim 12 wherein
sampling the output of the phase detector includes sampling the output of the phase detector with a single pole low pass digital filter.

17. The method of claim 12 further comprising:
providing a multi-bit output signal from the digital filter, and
using the output signal from the digital filter to at least partially control a clock generator to provide a recovered clock signal.

18. The method of claim 17 further comprising:
varying a time constant of the digital filter from a first low time constant at a beginning of acquisition to a second high time constant in response to determining that phase lock of the first and second signals has been achieved.

19. A system comprising:
a bus;
a first integrated circuit device coupled to the bus to provide a phase-encoded data signal; and
a second integrated circuit device coupled to the bus, the second integrated circuit device including a clock and data recovery circuit, the clock and data recovery circuit including,
a digital phase detector to receive the phase-encoded data signal and a clock signal, the digital phase detector to provide one of a lead and a lag signal to indicate whether the phase-encoded data signal leads or lags the clock signal in response to receiving an enable check signal, and
a digital filter to sample the one of the lead and lag output signal, the digital filter to provide a digital phase error signal to indicate a phase difference between the phase-encoded data signal and the clock signal.

20. The system of claim 19 wherein,
the bus is in accordance with a version of the peripheral control interface bus.

21. The system of claim 19 wherein,
the digital filter includes multiple inputs, each of the multiple inputs being coupled to receive the one of the lead and lag signals.

22. The system of claim 21 wherein,
the digital phase error signal is a multibit signal and wherein, the clock and data recovery circuit is to determine that phase-lock has been achieved in response to the digital phase error signal being substantially in a middle of a range of possible digital phase error signal values.

23. The system of claim 22 wherein,
the digital phase error signal is to be used to control a clock generator to provide a recovered clock signal.

24. The system of claim 22 wherein, the digital phase error signal is provided to an acquisition and tracking control circuit, the acquisition and tracking control circuit to provide one or more output signals to control a clock generator to generate a recovered clock signal associated with the phase-encoded data signal, the acquisition tracking and control circuit further to control a time constant of the digital filter.
